(19) United States
(12) Patent Application Publication
(10) Pub. No.: US 2024/0361492 A1
(43) Pub. Date: Oct. 31, 2024

(54) NUMERICAL MODELING OF CONDENSATE BANKING EFFECT EXTENDING TO WELL DRAINAGE AREA USING EFFECTIVE UPSTREAM MOBILITY

(71) Applicant: SAUDI ARABIAN OIL COMPANY, Dhahran (SA)

(72) Inventors: Shahid Manzoor, Dhahran (SA); Jubril Oluwa, Dhahran (SA); Tareq Shaalan, Dhahran (SA)

(73) Assignee: SAUDI ARABIAN OIL COMPANY, Dhahran (SA)

(21) Appl. No.: 18/307,562

(22) Filed: Apr. 26, 2023

(51) Int. Cl. G01V 99/00

(52) U.S. Cl. CPC G01V 20/00

(57) ABSTRACT

A method to perform reservoir simulation of a reservoir is disclosed. The method includes constructing a wellbore drainage region for a wellbore in a reservoir grid for the reservoir simulation, constructing a drainage pseudo-pressure table for each grid block in the wellbore drainage region, calculating, based on the drainage pseudo-pressure table, a drainage pseudo-pressure factor for said each grid block in the wellbore drainage region, performing, based on the drainage pseudo-pressure factor for said each grid block in the wellbore drainage region, the reservoir simulation of the reservoir to generate a reservoir simulation result, and performing, based on the reservoir simulation result, well production of the reservoir, where the drainage pseudo-pressure factor is used in the reservoir simulation to model a condensate banking phenomenon in the wellbore drainage region.

### BACKGROUND

Condensate is a low density and high API gravity (American Petroleum Institute gravity) hydrocarbon generally found in a gas reservoir. Gas reservoirs producing condensate in gas wells are referred to as gas condensate reservoirs. While the term “condensate” often refers to the liquid form of the low density and high API gravity hydrocarbon found in gas condensate reservoirs, the term “condensate” is broadened throughout this disclosure to describe all phases of such hydrocarbon in gas condensate reservoirs.

When reservoir pressure drops below the dew point during gas reservoir production, condensate changes from gaseous phase to liquid phase (i.e., precipitates) in the reservoir around the well and rapidly accumulates as freshly produced gas continues to deposit additional liquid condensate near the well. The accumulation of liquid condensate near the well is referred to as the condensate banking phenomenon, which reduces the gas saturation and the gas well productivity.

### SUMMARY

In general, in one aspect, the invention relates to a method to perform reservoir simulation of a reservoir. The method includes constructing a wellbore drainage region for a wellbore in a reservoir grid for the reservoir simulation, constructing a drainage pseudo-pressure table for each grid block in the wellbore drainage region, calculating, based on the drainage pseudo-pressure table, a drainage pseudo-pressure factor for said each grid block in the wellbore drainage region, performing, based on the drainage pseudo-pressure factor for said each grid block in the wellbore drainage region, the reservoir simulation of the reservoir to generate a reservoir simulation result, and performing, based on the reservoir simulation result, well production of the reservoir, wherein the drainage pseudo-pressure factor is used in the reservoir simulation to model a condensate banking phenomenon in the wellbore drainage region.

In general, in one aspect, the invention relates to a reservoir simulator to perform reservoir simulation of a reservoir. The reservoir simulator includes a computer processor, and memory storing instructions, when executed by the computer processor comprising functionality for constructing a wellbore drainage region for a wellbore in a reservoir grid for the reservoir simulation, constructing a drainage pseudo-pressure table for each grid block in the wellbore drainage region, calculating, based on the drainage pseudo-pressure table, a drainage pseudo-pressure factor for said each grid block in the wellbore drainage region, performing, based on the drainage pseudo-pressure factor for said each grid block in the wellbore drainage region, the reservoir simulation of the reservoir to generate a reservoir simulation result, and facilitating, based on the reservoir simulation result, well production of the reservoir, wherein the drainage pseudo-pressure factor is used in the reservoir simulation to model a condensate banking phenomenon in the wellbore drainage region.

In general, in one aspect, the invention relates to a system that includes a wellbore for performing well production of a reservoir, and a reservoir simulator comprising a computer processor and memory storing instructions, when executed by the computer processor comprising functionality for constructing a wellbore drainage region for the wellbore in a reservoir grid for the reservoir simulation, constructing a drainage pseudo-pressure table for each grid block in the wellbore drainage region, calculating, based on the drainage pseudo-pressure table, a drainage pseudo-pressure factor for said each grid block in the wellbore drainage region, performing, based on the drainage pseudo-pressure factor for said each grid block in the wellbore drainage region, the reservoir simulation of the reservoir to generate a reservoir simulation result, and facilitating, based on the reservoir simulation result, well production of the reservoir, wherein the drainage pseudo-pressure factor is used in the reservoir simulation to model a condensate banking phenomenon in the wellbore drainage region.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1A-1C show a system in accordance with one or more embodiments.

FIGS. 2A-2B show method flowcharts in accordance with one or more embodiments.

FIGS. 3A-3H shows an example in accordance with one or more embodiments.

FIG. 4 shows a computing system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (for example, first, second, third) may be used as an adjective for an element (that is, any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include a method and system for performing reservoir simulation in a reservoir that accurately models the condensate banking phenomenon. In one or more embodiments of the invention, the reservoir simulation is perform by constructing a wellbore drainage region for a wellbore in a reservoir grid, constructing a drainage pseudo-pressure table for each grid block in the wellbore drainage region, calculating a drainage pseudo-pressure factor for each grid block in the wellbore drainage region based on the drainage pseudo-pressure table, performing the reservoir simulation of the reservoir based on the drainage pseudo-pressure factor to generate a reservoir simulation result, and performing well production of the reservoir based on the reservoir simulation result. In one or more embodiments, the drainage pseudo-pressure factor is used in the reservoir simulation to model a condensate banking phenomenon in the wellbore drainage region.

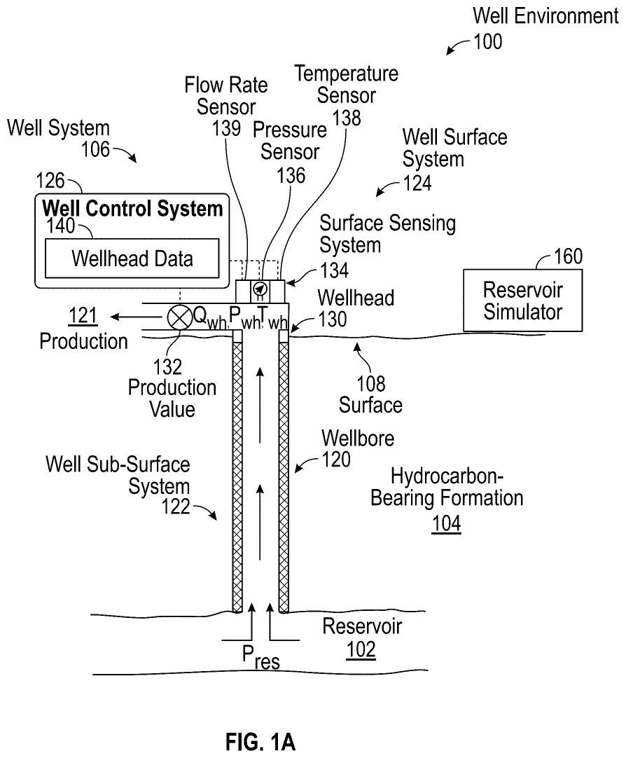

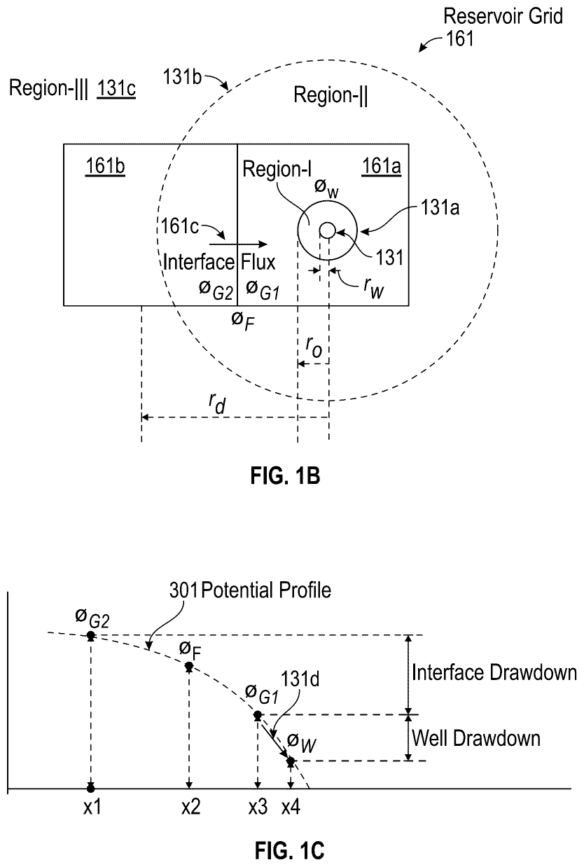

FIG. 1A shows a schematic diagram in accordance with one or more embodiments. More specifically, FIG. 1A illustrates a well environment (100) that includes a hydrocarbon reservoir (“reservoir”) (102) located in a subsurface hydrocarbon-bearing formation (“formation”) (104) and a well system (106). In one or more embodiments of the disclosure, the reservoir (102) is a gas reservoir to produce condensate, referred to as a gas condensate reservoir. The hydrocarbon-bearing formation (104) may include a porous or fractured rock formation that resides underground, beneath the Earth's surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock (referred to as formation layers) having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

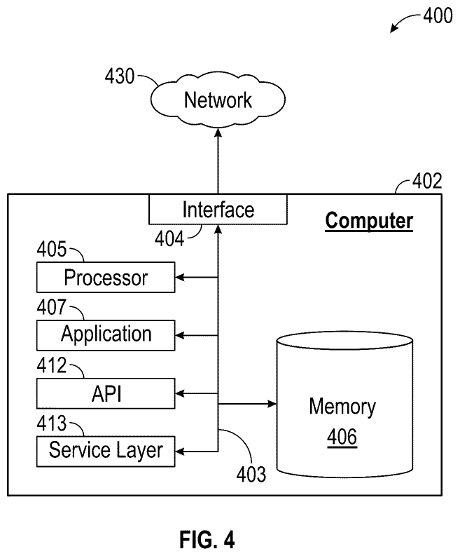

In some embodiments, the well system (106) includes a wellbore (120), a well sub-surface system (122), a well surface system (124), and a well control system (“control system”) (126). In one or more embodiments of the disclosure, the wellbore (120) is a gas well to produce condensate, referred to as a gas condensate well. The control system (126) may control various operations of the well system (106), such as well production operations, well completion operations, well maintenance operations, and reservoir monitoring, assessment and development operations. In some embodiments, the control system (126) includes a computer system that is the same as or similar to that of the computer system (400) described below in FIG. 4 and the accompanying description.

The wellbore (120) may include a bored hole that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “down-hole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) into the hydrocarbon-bearing formation (104) or the reservoir (102) during monitoring operations (e.g., during in situ logging operations).

In some embodiments, during operation of the well system (106), the control system (126) collects and records wellhead data (140) for the well system (106). The wellhead data (140) may include, for example, a record of measurements of wellhead pressure (P_{wh}) (e.g., including flowing wellhead pressure), wellhead temperature (T_{wh}) (e.g., including flowing wellhead temperature), wellhead production rate (Q_{wh}) over some or all of the life of the well system (106), and water cut data. In some embodiments, the measurements are recorded in real-time, and are available for review or use within seconds, minutes or hours of the condition being sensed (e.g., the measurements are available within 1 hour of the condition being sensed). In such an embodiment, the wellhead data (140) may be referred to as “real-time” wellhead data (140). Real-time wellhead data (140) may enable an operator of the well system (106) to assess a relatively current state of the well system (106), and make real-time decisions regarding development of the well system (106) and the reservoir (102), such as on-demand adjustments in regulation of production flow from the well.

In some embodiments, the well sub-surface system (122) includes casing installed in the wellbore (120). For example, the wellbore (120) may have a cased portion and an uncased (or “open-hole”) portion. The cased portion may include a portion of the wellbore having casing (e.g., casing pipe and casing cement) disposed therein. The uncased portion may include a portion of the wellbore not having casing disposed therein. In some embodiments, the casing includes an annular casing that lines the wall of the wellbore (120) to define a central passage that provides a conduit for the transport of tools and substances through the wellbore (120). For example, the central passage may provide a conduit for lowering logging tools into the wellbore (120), a conduit for the flow of production (121) (e.g., oil and gas) from the reservoir (102) to the surface (108), or a conduit for the flow of injection substances (e.g., water) from the surface (108) into the hydrocarbon-bearing formation (104). In some embodiments, the well sub-surface system (122) includes production tubing installed in the wellbore (120). The production tubing may provide a conduit for the transport of tools and substances through the wellbore (120). The production tubing may, for example, be disposed inside casing. In such an embodiment, the production tubing may provide a conduit for some or all of the production (121) (e.g., oil and gas) passing through the wellbore (120) and the casing.

In some embodiments, the well surface system (124) includes a wellhead (130). The wellhead (130) may include a rigid structure installed at the “up-hole” end of the wellbore (120), at or near where the wellbore (120) terminates at the Earth's surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (121). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

Keeping with FIG. 1A, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120).

In some embodiments, the surface sensing system (134) includes a surface pressure sensor (136) operable to sense the pressure of production (121) flowing through the well surface system (124), after it exits the wellbore (120). The surface pressure sensor (136) may include, for example, a wellhead pressure sensor that senses a pressure of production (121) flowing through or otherwise located in the wellhead (130). In some embodiments, the surface sensing system (134) includes a surface temperature sensor (138) operable to sense the temperature of production (121) flowing through the well surface system (124), after it exits the wellbore (120). The surface temperature sensor (138) may include, for example, a wellhead temperature sensor that senses a temperature of production (121) flowing through or otherwise located in the wellhead (130), referred to as “wellhead temperature” (Twh). In some embodiments, the surface sensing system (134) includes a flow rate sensor (139) operable to sense the flow rate of production (121) flowing through the well surface system (124), after it exits the wellbore (120). The flow rate sensor (139) may include hardware that senses a flow rate of production (121) (Qwh) passing through the wellhead (130).

In some embodiments, the well system (106) includes a reservoir simulator (160). For example, the reservoir simulator (160) may include hardware and/or software with functionality for generating one or more reservoir models regarding the hydrocarbon-bearing formation (104) and/or performing one or more reservoir simulations. For example, the reservoir simulator (160) may store well logs and data regarding reservoir samples for performing simulations. For example, the reservoir samples may include core samples and/or condensate fluids sample obtained from the reservoir. A reservoir simulator may further analyze the well log data, the reservoir sample data, seismic data, and/or other types of data to generate and/or update the one or more reservoir models. While the reservoir simulator (160) is shown at a well site, embodiments are contemplated where reservoir simulators are located away from well sites. In some embodiments, the reservoir simulator (160) may include a computer system that is similar to the computer system (400) described below with regard to FIG. 4 and the accompanying description.

In a typical reservoir simulation, a mathematical model of the reservoir includes a set of partial differential equations representing reservoir and well flows that are solved numerically. Numerical solution involves time and space/domain discretization replacing differential equations with difference equations. Time discretization refers to division of time into a sequence of time steps. In each time step, after discretization is solved iteratively, a non-linear system is linearized using Newton method, which may take several Newton iterations to converge. Space/domain discretization, also called grid generation, refers to division of the reservoir domain into a reservoir grid of small grid blocks. A grid is a tessellation of a set of contiguous polygonal (2D) or polyhedral (3D) objects referred to as grid blocks/cells/elements/control volumes. The grid generation is a process of discretization of the reservoir using both structured and more complex unstructured grid blocks to accurately represent the geometry of the reservoir. Local grid refinement (i.e., LGR where a finer grid is selectively embedded inside a coarse grid) is also a feature provided by many simulators to more accurately represent the near wellbore multi-phase flow effects.

Numerical schemes used in reservoir simulation are control volume distributed (CVD). Rock properties such as permeability and porosity, and flow properties such as pressure, temperature, and composition (saturation) are assumed piecewise constant within a control volume (i.e., grid block). However, reservoir and flow properties may jump by order of magnitude across the faces of the control volumes (i.e., grid blocks). Consequently, property distribution in reservoir simulation is stair step, and rate of change of a property across grid blocks depends on grid resolution. Lack of definition within a single grid block and sharp changes in pressure and saturation across the grid blocks create several physical, numerical, and convergence problems during the reservoir simulation.

In numerical simulation, dynamic interaction between hydrocarbon reservoirs and wells may be modeled using reservoir boundary conditions in the form of well controls to match historical data and/or define operational limits for reservoir forecasting. For example, the reservoir simulation may be used to predict or forecast field performance and ultimate recovery for various field development scenarios to evaluate the effects on recovery of different operational conditions and compare economics of different recovery methods.

FIGS. 1B and 1C show schematics of modeling condensate banking extending to a wellbore drainage region in accordance with one or more embodiments disclosed herein. Specifically, FIG. 1B shows a grid block A (161a) and a grid block B (161b) of the reservoir grid (161) that is a set of contiguous grid blocks used by the reservoir simulator (160) for representing the reservoir (102) depicted in FIG. 1A above. In particular, the grid block A (161a) and grid block B (161b) are part of a two-dimensional (2D) planar portion of the reservoir grid (161). In a compositional case where the reservoir (102) intersects multiple formation layers, the 2D planar portion may correspond to one of the formation layers, referred to as the layer l. Further, the grid block A (161a) is a perforated grid block encompassing a perforation (131) that represents the wellbore (120) depicted in FIG. 1A above.

During the reservoir simulation, the reservoir simulator (160) computes fluid flow as a gradient of a potential field in the reservoir model. Mathematically speaking, the gradient is a vector while the magnitude of the gradient is referred to as the flux. The value of the potential field corresponding to a grid block is referred to as the grid block potential. The value of the potential field corresponding to a boundary between two neighboring grid blocks is referred to as the interface potential. The value of the potential field corresponding to a well is referred to as the well potential. FIG. 1C shows a profile plot of the potential (i.e., potential profile (301)) of the grid block A (161a) and grid block B (161b) in the reservoir simulation. In one or more embodiments of the invention, the potential field in the reservoir simulation corresponds to fluid pressure in the reservoir. In such embodiments, the terms “potential” and “pressure” may be used interchangeably unless otherwise specified.

As shown in FIG. 1B, the grid block A (161a) is a perforated grid block encompassing a perforation (131) that has a radius (r_{w}) to represent the wellbore (120) depicted in FIG. 1A above. In other words, the radius (r_{w}) corresponds to the wellbore radius of the wellbore (120). In the compositional case where the grid block A (161a) is part of the formation layer l of the reservoir (102), the perforation (131) is referred to as the layer/completion l. The grid block A (161a) and grid block B (161b) are neighboring grid blocks having Ø_{G1} and Ø_{G2} as their respective grid block potentials. Ø_{F} denotes the interface potential between the grid block A (161a) and grid block B (161b). Ø_{W} denotes the well potential at the perforation (131) representing the wellbore (120). The interface flux (161c) represents the fluid flow from the grid block B (161b) into the grid block A (161a).

As shown in FIG. 1C, the horizontal axis corresponds to the positions along a longitudinal direction of the grid block A (161a) and grid block B (161b), and the vertical axis corresponds to a measure of the potential. In the potential profile (301), the grid block potential Ø_{G2}, the grid block potential Ø_{G1}, the interface potential OF, and the well potential Ow are respectively designated to positions x1, x2, x3, and x4, which in turn correspond to the center of the grid block B (161b), the interface between the grid block A (161a) and grid block B (161b), the center of the grid block A (161a), and the perforation (131), respectively, as depicted in FIG. 1B above. The difference between the grid block potential Ø_{G2} and the grid block potential Ø_{G1} is referred to as the interface drawdown. The difference between the grid block potential Ø_{G1} and the well potential Ø_{W} is referred to as the well drawdown. The slope of the potential profile (301) (i.e., the gradient of the potential field) near the position x4 corresponds to the wellbore inflow flux (131d), i.e., fluid flow into the perforation (131) representing the wellbore (120).

The well inflow can be calculated by inverting a two-point flux approximation scheme. The potential drops (ΔØ) caused by producing fluid from a perforated grid block depends on flow and rock properties of reservoir and wellbore, and the potential drop decreases monotonically as it moves away from perforated grid block. In particular, potential drop between two contiguous points along the potential profile is the difference of potential between the two points. Phase potential (ΔØₚ) for a phase p is given by:

$$Δ {∅}_{p} = Δ {P}_{p} + Δ {P}_{c , p} - {ρ}_{p} g Δ h \qquad Eq . ( 1 a )$$

where ΔP is the pressure drop (referred to as “drawdown”), ΔP_{c,p} is difference between phase capillary pressure, and ρₚgΔh defines pressure difference due to gravity head (Δh).

In reservoir simulation, flow fields are solved for a selected phase (often oil-phase) pressure. Other phase-pressures, if required, are calculated using capillarity between the phases. Therefore, for the selected phase (p), there is no capillarity and potential is related to pressure by

$$Δ {∅}_{p} = Δ {P}_{p} - {ρ}_{p} g Δ h \qquad Eq . ( 1 b )$$

Further, reservoir geometries are comprised of layer cake structure, in vertical direction layer thickness/depth is in feet (few feet), whereas reservoir layers often extend areal in orders of kilometers. In well drainage region, cells selected to resolve pressure dependence are neighbors to each other, where Δh both in areal and vertical directions is negligible, i.e., gravity head term (ρₚgΔh) is negligible. Consequently, in such embodiment, the term pressure and potential are used interchangeably, unless stated otherwise.

$$Δ {∅}_{p} ≅ Δ {P}_{p} \qquad Eq . ( 1 c )$$

In general, as shown in FIG. 1B, discrete grid block size used in reservoir simulation is much larger than that of the wellbore (r_{w}) and would introduce singularities if the well is discretized similar to that of grid block size. Well productivity index (WIₗ) is introduced to couple wells to the reservoir by relating wellbore pressure and flow to the grid block parameters. Specifically, the well productivity index (WIₗ) is a measure of ability of the reservoir to produce fluid flow in relation to the reservoir pressure. The well productivity index (WIₗ) can be mathematically expressed as the ratio of volumetric flow produced by a well (measured in bbl/day) to the pressure loss (referred to as pressure drawdown) between the reservoir and the wellbore (measured in psi).

The well inflow performance relationship for the compositional case for a given phase p of a hydrocarbon component c through the layer/completion l (e.g., perforation (131)) connected to grid block Gᵢ (e.g., grid block A (161a)) is given by:

$${q}_{c , l} = {WI}_{l} \times {λ}_{c , l} \times ( {P}_{Gi} - {P}_{wf} - {ρ}_{mix} g Δ h ) = {WI}_{l} \times {λ}_{c , l} \times ( {∅}_{{G}_{i}} - {∅}_{w} ) \qquad Eq . ( 2 )$$

where λ_{c,l} is the upstream hydrocarbon component molar mobility (referred to as upstream mobility), P_{Gi} is grid block pressure, P_{wf} is well bottom hole pressure (wellbore pressure at first layer/completion) and μₘᵢₓgΔh is the gravity head. Note that in well inflow performance relationship well stream mixture density (ρₘᵢₓ) is used, and Δh is the depth difference between grid block Gᵢ and first layer/completion. In general, the mobility corresponds to a ratio of permeability over viscosity. For a hydrocarbon producing completion, the upstream hydrocarbon component molar mobility is given by:

$${λ}_{c , l} = {( \frac{{k}_{ro} {ρ}_{o}}{{μ}_{0}} )}_{l} {x}_{c} + {( \frac{{k}_{rg} {ρ}_{g}}{{μ}_{g}} )}_{l} {y}_{c} \qquad Eq . ( 3 )$$

where kᵣₒ, ρₒ, and μₒ respectively represent relative permeability, molar density, and viscosity relating to hydrocarbon in oil phase, k_{rg}, ρ_{g}, and μ_{g} respectively represent relative permeability, molar density, and viscosity relating to hydrocarbon in gas phase, and x_{c} and y_{c} respectively represent oil and gas component-mole-fraction. The quantities defining mobility term (λ_{c,l}) are a function of saturation and pressure. In a reservoir simulator, wellbore and reservoir quantities are synchronized dynamically passing information from the wellbore to the reservoir and vice-versa. In general, molar mobility λ_{c,l} is calculated using grid block quantities (pressure and saturations) and used in well inflow performance relationship, i.e., in Eq. (2).

Well-deliverability, measured by the well productivity index (WIₗ), is a critical issue in the development of many gas-condensate reservoirs. In a gas-condensate system, production data for some gas-condensate wells have shown that well productivity is significantly reduced when wellbore flowing-bottom-hole-pressure (FBHP) drops below the saturation pressure of in-place fluid. This is true even for lean gas condensate reservoirs where maximum liquid drop out in the deep reservoir is as low as 1%. The phenomenon is referred to as the condensate banking effect where liquid phase accumulates in the wellbore region, forming a ring which progressively extends to the well drainage area and impairs the gas deliverability. The well drainage area is a subset of reservoir area or volume that is drained by the well. As shown in FIG. 1B, the well drainage area (131b) is depicted as the region-II within a circular contour with the radius r_{d}. In the vicinity of gas-condensate wells where condensate saturations reach high values and oil relative permeability may exceed gas relative permeability, the gas dominated flow behavior predicted by reservoir simulation may not be correct, and use of upstream mobility in the reservoir simulation leads to over prediction of field performance. The local grid refinement (LGR) using fine grids in near wellbore (drainage) regions may be used to reduce pressure dependence of upstream mobility. Nevertheless, local grid refinement results in significant added computational cost, and is impractical for large scale field simulations with thousands of wells. Alternatively, to model condensate banking, multiphase transient wellbore model involving pseudo-pressure integral has also been used. In this multiphase transient wellbore model, Eq. (2) is modified into Eq. (4) below.

$${q}_{c , l} = β \times {WI}_{l} \times {λ}_{c , l} \times ( {∅}_{{G}_{i}} - {∅}_{w} ) \qquad Eq . ( 4 )$$

Factor β is named as pseudo-pressure factor and is computed to resolve (i.e., include the effect of] pressure dependence of fluid and rock properties, e.g., upstream mobility (Δ_{c,l@P}_{_{Gi}}) from wellbore radius (r_{w}) to Peacemen's equivalent radius (rₒ). Resolving the pressure/potential dependence of fluid and rock properties such as the upstream mobility leads to more accurate modeling of the condensate banking phenomenon. The Peacemen's equivalent radius (rₒ) is a pressure equivalent radius depicted in FIG. 1B as rₒ. In FIG. 1B, the pressure equivalent radius is the distance from the perforation (131) to a circular contour (131a) where the local pressure is equal to the nodal average pressure of the grid block, i.e., the grid block pressure P_{Gi} for the grid block A (161a). The pressure equivalent radius computed using the Peacemen's formula is referred to as the Peacemen's equivalent radius. The region between the circular contour (131a) and the wellbore radius (r_{w}) is referred to as the region-I.

The pseudo-pressure factor β may be computed using Eq. (5) below.

$$β = \frac{{\int }_{∅ w}^{{∅}_{Gi}} {λ}_{TGMM} d ∅}{{λ}_{TGMM @ {∅}_{G i}} \times ( {∅}_{Gi} - {∅}_{w} )} \qquad Eq . ( 5 )$$

where λ_{TGMM} is total generalized molar mobility given by:

$${λ}_{TGMM} = {\sum }_{c = 1}^{ncomp} ( \frac{{k}_{ro} {ρ}_{o}}{{μ}_{o}} {x}_{c} + \frac{{k}_{rg} {ρ}_{g}}{{μ}_{g}} {y}_{c} ) = \frac{{k}_{ro} {ρ}_{o}}{{μ}_{o}} + \frac{{k}_{rg} {ρ}_{g}}{{μ}_{g}} \qquad Eq . ( 5 A )$$

As noted above, the summation index c corresponds to a hydrocarbon component in the compositional case, and the summation upper limit ncomp corresponds to the number of hydrocarbon components in the compositional case. The use of pseudo-pressure approach is limited to Peaceman's equivalent radius (rₒ), which for uniform isotropic grid and properties is only 0.198 (⅕) times of perforated grid block size, depicted in FIG. 1B as the width/height of the grid block A (161a).

In general, gas condensate flow and/or saturations are classified into three regions as depicted in FIG. 1B:

Region-I is the near wellbore region where gas/oil flow is steady state and condensate build up is high. The near wellbore region is from wellbore radius (r_{w}) to Peaceman's equivalent radius (rₒ).

Region-II is the wellbore drainage region where pressure drop is relatively low and exhibits gas flow at a somewhat reduced permeability with condensate saturation being low but increasing in time.

Region-III (131c) is the rest of the reservoir away from the wellbore drainage region, where pressure drop is negligible and assumption of upstream mobility is valid.

Potential (e.g., pressure) drop in the wellbore drainage region across the grid block interfaces can be significant. This is true in particular for gas condensate reservoirs with low to moderate permeability (e.g., due to poor rocks) and gas-condensate wells with high productivity indices due to fracking involving negative/stimulation skin. In such cases due to negative skin, the well productivity index (WIₗ) is high, and consequently as described below, the well drawdown (i.e., pressure drop) is relatively low within the region-I. Furthermore, in the neighboring grid blocks, the interface drawdown is high due to poor rocks. Therefore, the use of pseudo-pressure integral limited to region-I resolves pressure dependence of upstream mobility/flux only partially in modeling the condensate banking phenomenon. To date no physical or numerical model exists to model condensate banking phenomenon extending to the wellbore drainage region-II.

In one or more embodiments of the invention, the condensate banking modeling is extended to the wellbore drainage region as described below.

Potential drop across an interface is given by the difference of potential between grid blocks sharing the interface, and is used in flux calculations. In a manner similar to well inflow performance relationship (i.e., Eq. (2)), the interface flux (F_{Γ}_{ᵢₙ}) through an arbitrary interface F is given by:

$${F}_{{Γ}_{in}} = - T \times {λ}_{upstrm} \times ( {∅}_{G 1} - {∅}_{G 2} ) \qquad Eq . ( 6 )$$

where T is interface transmissibility, and λᵤₚₛₜᵣₘ is upstream molar mobility, and in reservoir simulation is computed at upstream pressure (i.e., potential). In one or more embodiments, the use of pseudo-pressure integral is extended to the wellbore drainage region to resolve pressure dependence of flow and rock properties. Specifically, the wellbore drainage region is identified around wellbores and the pseudo-pressure integral is extended to the identified wellbore drainage region beyond the Peacemen's radius. Extending the pseudo-pressure integral to the wellbore drainage region resolves pressure dependence of upstream mobility and/or flux more completely to improve modeling of the condensate banking phenomenon. Drainage pseudo-pressure option replaces the traditional single point upstream drainage mobility (Eq. (6)) with an integrated form that more accurately predicts condensate banking in the high drawdown regions around the wellbore, and is independent of well and grid geometry. The resulting modified interface influx relationship is then given by:

$${F}_{{Γ}_{in}} = - α \times T \times {λ}_{upstrm} \times ( {∅}_{G 1} - {∅}_{G 2} ) \qquad Eq . ( 7 )$$

Factor α is referred to as the drainage-pseudo-pressure factor and is computed to resolve pressure dependence of fluid and rock properties (e.g., upstream mobility) for all the grid blocks within the wellbore drainage region. For a flux stream entering into an interface Γᵢₙ with Øᵤₚₛₜᵣₘ and Ø_{dwnstrm} being upstream and downstream potential respectively, the factor α is given by:

$$α = \frac{{\int }_{∅ dwnstrm}^{{∅}_{upstrm}} {λ}_{TGMM} d ∅}{{λ}_{TGMM @ {∅}_{upstrm}} \times ( {∅}_{upstrm} - {∅}_{dwnstrm} )} \qquad Eq . ( 8 )$$

Note that Øᵤₚₛₜᵣₘ is always less than Ø_{dwnstrm}. In FIG. 1B, for a producer well Øᵤₚₛₜᵣₘ=Ø_{G2} and Ø_{dwnstrm}=Ø_{G1}.

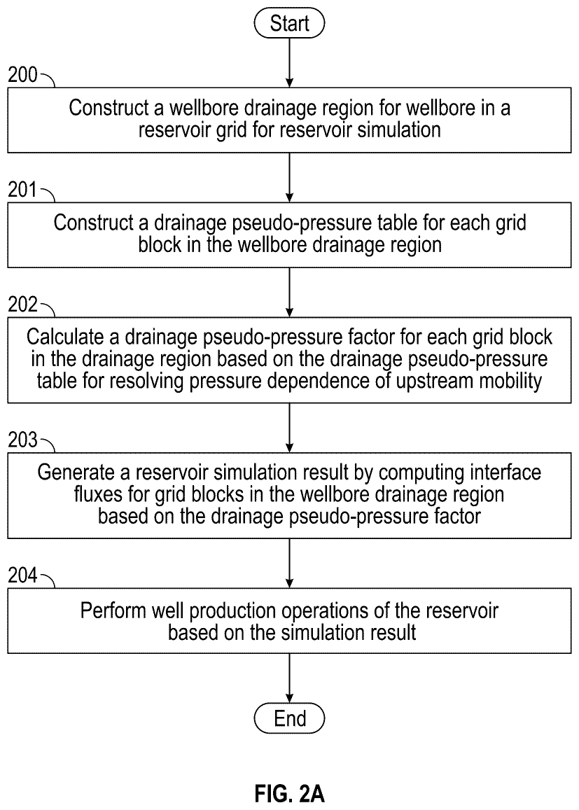

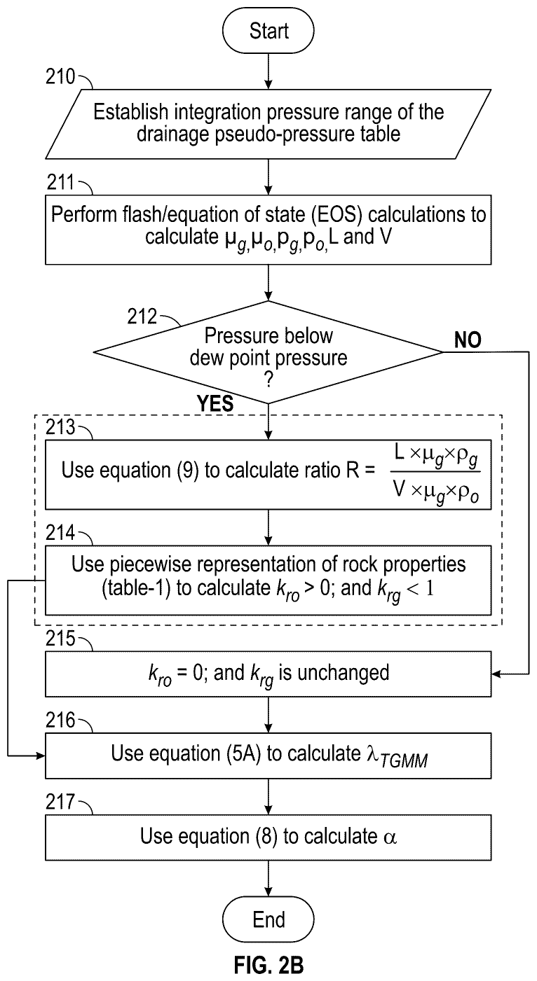

FIGS. 2A-2B show flowcharts in accordance with one or more embodiments disclosed herein. One or more of the steps in FIGS. 2A-2B may be performed by the components of the well environment (100) and the reservoir simulator (160), discussed above in reference to FIGS. 1A-1B. In one or more embodiments, one or more of the steps shown in FIGS. 2A-2B may be omitted, repeated, and/or performed in a different order than the order shown in FIGS. 2A-2B. Accordingly, the scope of the disclosure should not be considered limited to the specific arrangement of steps shown in FIGS. 2A-2B.

FIG. 2A shows the flowchart of a method to compute effective upstream mobility based on the drainage pseudo-pressure integral. The method flowcharts includes Step 200, Step 201, and Step 202. In one or more embodiments, Step 200 is performed at the beginning of the reservoir simulation while Step 201 and Step 202 are performed at the beginning of each time step of the reservoir simulation. In additional to being performed at the beginning of the reservoir simulation, Step 200 may be subsequently repeated subject to the user specified frequency.

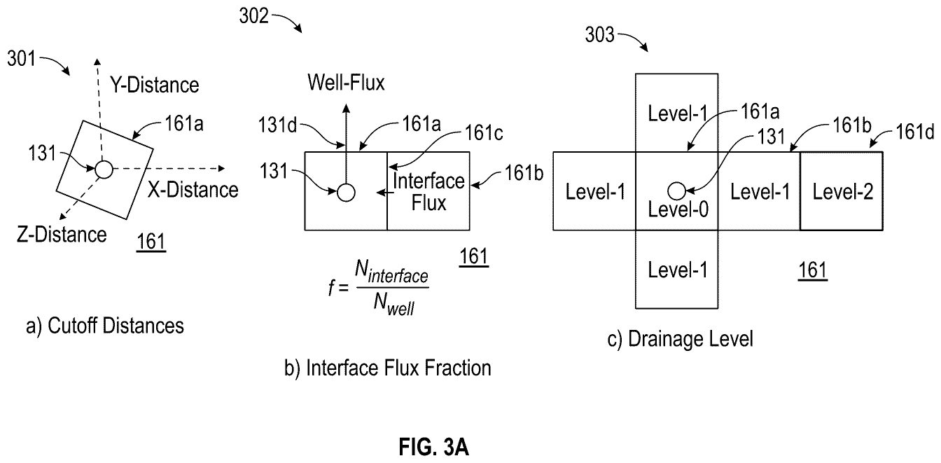

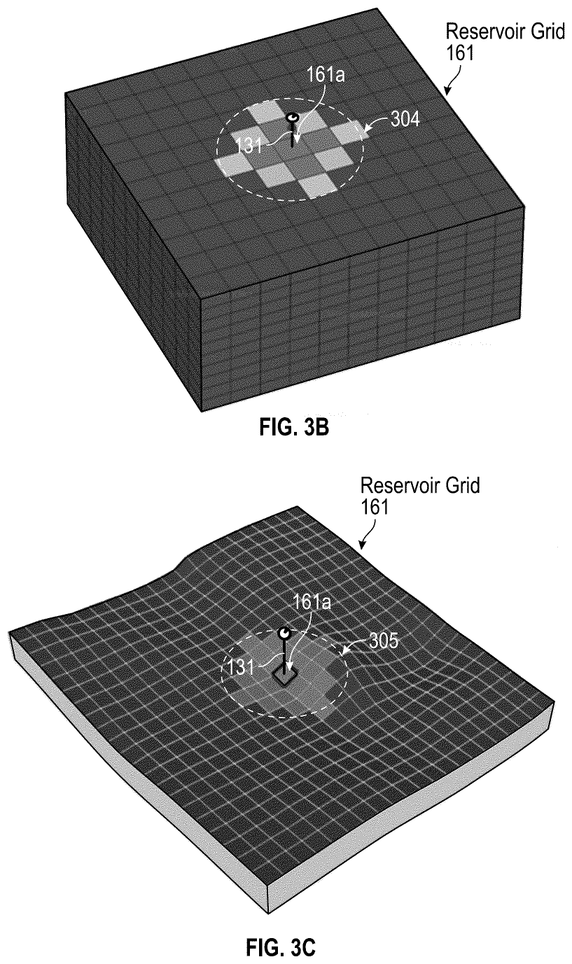

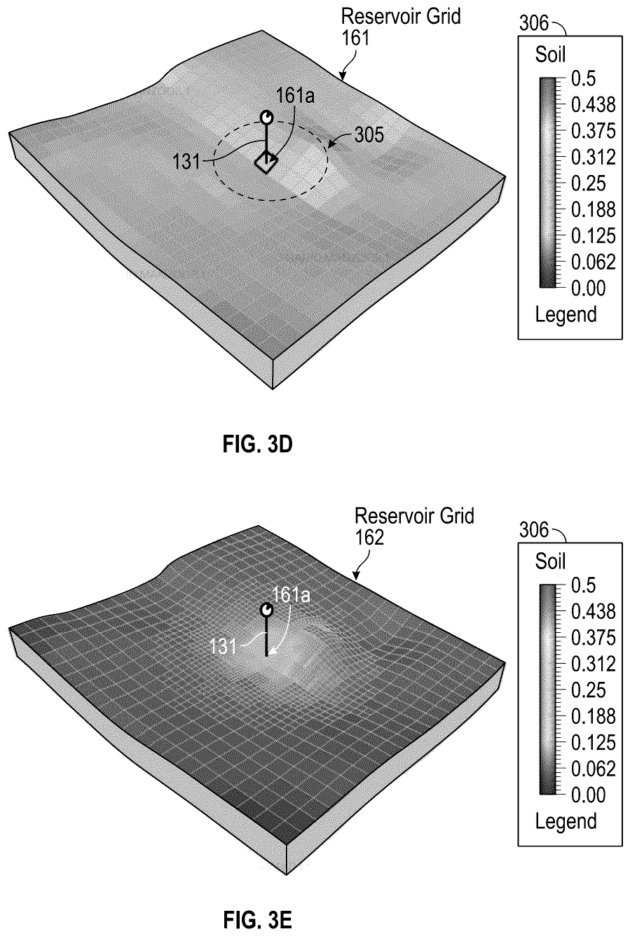

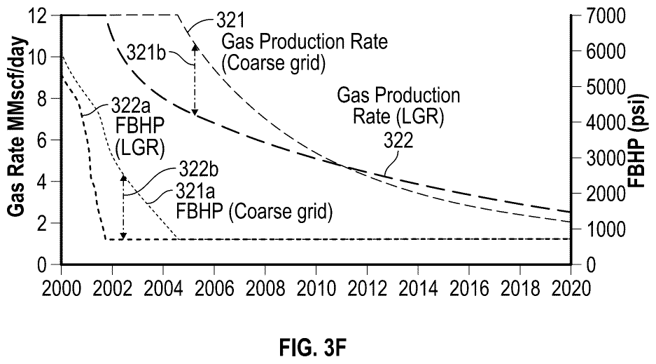

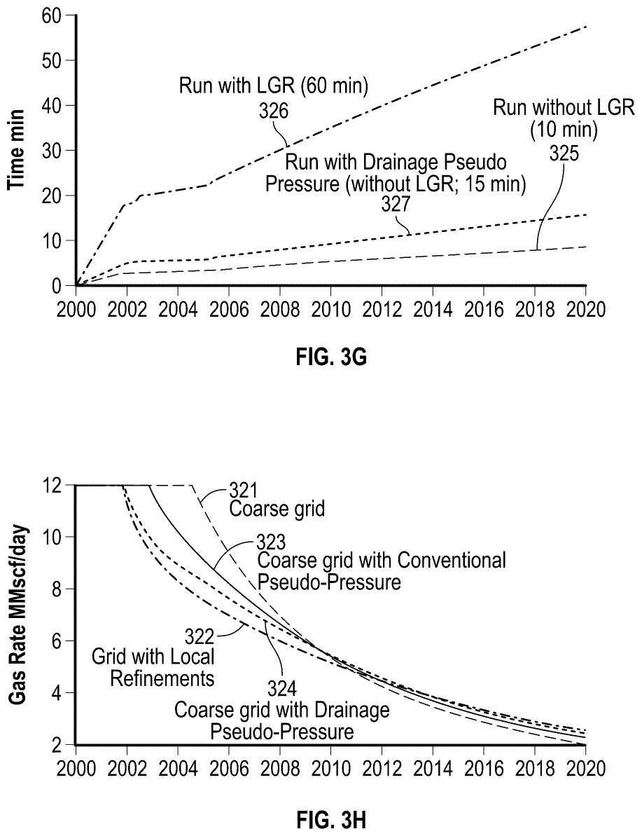

Initially in Step 200, wellbore drainage regions are constructed around wellbores in the field. In the near wellbore region of each well of the reservoir, grid blocks defining the wellbore drainage region are selected as candidate to resolve pressure dependence of upstream mobility. Starting with the perforated grid block, grid blocks in the neighborhood of the perforated cell are selected using an adjacency list to traverse grid block interfaces. In one or more embodiments, the selection criterion is based on a user specified cut off distance in X, Y, and Z directions that defines how far to traverse from the perforated grid block. An example plot is shown in FIG. 3A that illustrates the X, Y, and Z coordinates for defining the cut off distance relative to the perforation (131) in the perforated grid block A (161a) of the reservoir grid (161).

In one or more embodiments, the selection criterion is based on a user specified minimum cut off flux fraction, which is the minimum value of the relative flux (i.e., flux fraction) f given by

$$f = \frac{{N}_{interface}}{{N}_{well}} < 1$$

where N_{well} denotes the wellbore inflow flux (measured in moles drawn/produced by the well) and N_{interface} denotes the interface flux. Because the interface flux of neighboring grid blocks decreases as the distance of the grid block interface from the perforated grid block increases, the grid blocks associated with the relative flux exceeding the user specified minimum cut off flux fraction are selected as the wellbore drainage region. In other words, the grid blocks associated with the relative flux less than the user specified minimum cut off flux fraction are excluded from the wellbore drainage region. An example plot (302) is shown in FIG. 3A that illustrates the relative flux based on the interface flux (161c) and the wellbore inflow flux (131d) for defining the cut off flux fraction relative to the interface between the perforated grid block A (161a) and the neighboring grid block B (161b) of the reservoir grid (161).

In one or more embodiments, the selection criterion is based on a user specified minimum drainage level for selecting the grid blocks. The drainage level of a grid block corresponds to a hop-distance of the grid block from the perforated grid block, which is the least number of grid blocks to traverse from the perforated grid block to the grid block, and vice versa. In particular, the perforated grid block is assigned the level-0, neighboring grid blocks sharing interface(s) with the perforated grid block are assigned the level-1. Further away, grid blocks having an interface common with those of level-1 grid blocks are assigned the level-2, and so on and so forth. An example plot (303) is shown in FIG. 3A that illustrates the drainage levels of the perforated grid block A (161a), the neighboring grid block B (161b), and the further neighboring grid block D (161d) for defining the minimum drainage level to select the grid blocks included in the well drainage area. FIG. 3B shows an example wellbore drainage region (304) that includes all grid blocks of level-0, level-1, and level-2 centering at the grid block A (161a) in the reservoir grid (161). FIG. 3C shows an example wellbore drainage region (305) that includes all grid blocks of level-0, level-1, level-2, and level-3 centering at the grid block A (161a) in the reservoir grid (161).

In Step 201, a drainage pseudo-pressure table is constructed for each grid block with outgoing fluxes in the wellbore drainage region. For a particular grid block in the wellbore drainage region, the pressure at the center of the grid block defines the lower limit (i.e., minimum pressure) of the drainage pseudo-pressure table. Because each grid block can have multiple interfaces with outgoing fluxes, the maximum pressure of all neighboring grid blocks is used as the upper pressure limit of the drainage pseudo-pressure table. The drainage pseudo-pressure table covers possible range of interpolation pressures/potential, i.e., from the minimum pressure to maximum pressure as described above.

A constant composition experiment, or constant composition expansion (CCE) is a laboratory test performed as part of a routine pressure-volume-temperature (PVT) analysis that measures the change in volume of a reservoir fluid as a function of pressure. This change is determined by measuring the total volume of a sample of reservoir fluid at various pressures above and below the saturation pressure. The pressure-dependent volumes are normalized to the volume of the sample at the saturation pressure. In one or more embodiments, the CCE is performed within the minimum pressure and maximum pressure described above. The results of the CCE is used to construct a pressure versus total generalized molar mobility (λ_{TGMM}) table, which is the key portion of the drainage pseudo-pressure table. In performing the CCE, steady state conditions are assumed, with no net accumulation. This is achieved by enforcing that at any given pressure, ratio of hydrocarbon phase mobilities, and ratio of produced moles are same, e.g., according to Eq. (9) below.

$$\frac{L}{V} = \frac{{λ}_{o} ( {S}_{o} )}{{λ}_{g} ( {S}_{g} )} = \frac{{k}_{rg} {ρ}_{g} / {μ}_{g}}{{k}_{ro} {ρ}_{o} / {μ}_{o}} {\to }^{yields} R = \frac{{k}_{ro}}{{k}_{rg}} = \frac{L \times {μ}_{o} \times {ρ}_{g}}{V \times {μ}_{g} \times {ρ}_{o}} \qquad Eq . ( 9 )$$

where V and L are the vapor and liquid hydrocarbon moles, respectively obtained from the CCE experiment. Because relative permeability is a function of saturation, gas saturation (S_{g}) can be expressed, using constitutive relationship, in term of water saturation (S_{w}) and oil saturation (Sₒ), i.e., S_{g}=1−S_{w}+Sₒ.

Further, the water saturation (S_{w}) is assumed at (upstream) grid block pressure (P_{Gi}) and is assumed constant in the CCE. Equation (9) relates fluid and rock properties of hydrocarbons and is a non-linear equation in one variable, i.e., condensate (oil) saturation. Solving equation (9) iteratively can be computationally expensive, especially in full field simulations of a large number of wells.

In one or more embodiments, a piecewise representation of rock-properties is constructed for a range of condensate saturations to eliminate the iterative computation. Piecewise representation of rock-properties yields a lookup table constructed by varying oil saturation Sₒ from a minimum (e.g., Sₒᵣ) to a maximum possible value (1−S_{w}). The lookup table may include a user specified number of entries based on a user specified incremental saturation ΔS, and may be adapted to relative permeability ratio to improve accuracy and performance. TABLE 1 shows an example lookup table of piecewise representation of rock-properties. In the context that the rock property is saturation in the example, TABLE 1 is also referred to as the adaptive saturation lookup table. During CCE, for any integration pressures above dew point pressure with no drop out, kᵣₒ is zero and iterative solve is not required.

TABLE 1

| Sₒ | kᵣₒ | k_{rg} | kᵣₒ/k_{rg} |
|---|---|---|---|
| Sₒᵣ | ε | . . . | . . . |
| Sₒᵣ + ΔS | . . . | . . . | . . . |
| Sₒᵣ + 2ΔS | . . . | . . . | . . . |
| Sₒᵣ + 3ΔS | . . . | . . . | . . . |
| . . . | . . . | . . . | . . . |
| . . . | . . . | . . . | . . . |
| . . . | . . . | . . . | . . . |
| 1 − S_{w} | . . . | . . . | . . . |

TABLE 2 shows an example drainage pseudo-pressure table for a grid block in the wellbore drainage region.

TABLE 2

| Potential | ρ_{g} | μ_{g} | ρₒ | μ_{ο} | $\frac{L \times {μ}_{o} \times {ρ}_{g}}{V \times {μ}_{g} \times {ρ}_{o}}$ | k_{rg} (Interpolated) | kᵣₒ (Interpolated) | λ_{TGMM} |
|---|---|---|---|---|---|---|---|---|
| Ø_{Gi} | 0.00860 | 0.00029 | 0.00798 | 0.00148 | 0.1753370 | 0.16674 | 0.02928 | 5.0502 |
| Ø_{Gi} + δØ | 0.00881 | 0.00030 | 0.00806 | 0.00147 | 0.1424098 | 0.17645 | 0.02510 | 5.2814 |
| Ø_{Gi} + 2δØ | 0.00901 | 0.00031 | 0.00812 | 0.00147 | 0.1119425 | 0.18721 | 0.02098 | 5.5353 |
| Ø_{Gi} + 3δØ | 0.00920 | 0.00032 | 0.00817 | 0.00150 | 0.0850407 | 0.19816 | 0.01681 | 5.7885 |
| Ø_{Gi} + 4δØ | 0.00939 | 0.00033 | 0.00819 | 0.00155 | 0.0622850 | 0.20833 | 0.01293 | 6.0189 |
| Ø_{Gi} + 5δØ | 0.00956 | 0.00034 | 0.00820 | 0.00161 | 0.0433870 | 0.21758 | 0.00948 | 6.2261 |
| Ø_{Gi} + 6δØ | 0.00973 | 0.00035 | 0.00819 | 0.00168 | 0.0274237 | 0.22715 | 0.00623 | 6.4447 |
| Ø_{Gi} + 7δØ | 0.00989 | 0.00035 | 0.00819 | 0.00176 | 0.0133494 | 0.23609 | 0.00318 | 6.6478 |

Phase transition across dew point pressure (below is dry gas)

| | | | | | | | | |
|---|---|---|---|---|---|---|---|---|
| Ø_{Gi} + 9δØ | 0.01005 | 0.00036 | 0.00000 | 0.00000 | 0.0000000 | 1.00000 | 0.00000 | 27.953 |
| Ø_{Gj} | 0.01020 | 0.00037 | 0.00000 | 0.00000 | 0.0000000 | 1.00000 | 0.00000 | 27.903 |

For integration points with pressure below dew point, k_{rg} and kᵣₒ are computed by interpolating R (given by Eq. (9)) using an adaptive sₒ v.s. kᵣₒ/k_{rg} lookup table as shown in TABLE 3. Specifically, TABLE 3 shows a further example lookup table of piecewise representation of rock-properties, or the adaptive saturation lookup table.

TABLE 3

| Sₒ | kᵣₒ | k_{rg} | R = kᵣₒ/k_{rg} |
|---|---|---|---|
| 0.214868 | 0.0000000 | 0.27546566 | 0.00000000 |
| 0.245564 | 0.01717432 | 0.19720050 | 0.08709065 |
| 0.266027 | 0.03504156 | 0.15340272 | 0.22842857 |
| 0.286491 | 0.05293681 | 0.11585799 | 0.45691117 |
| 0.306955 | 0.07091946 | 0.08453135 | 0.83897226 |

In one or more embodiments, the drainage pseudo-pressure table is constructed at the start of every time step of the reservoir simulation. At the start of every time step, one drainage pseudo-pressure table is constructed for each grid block in the wellbore drainage region for calculating the drainage pseudo-pressure factor α. Further details of performing Step 201 are described in reference to FIG. 2B below.

In Step 202, the drainage pseudo-pressure (blocking) factor α is calculated for each grid block in the wellbore drainage region. Specifically, the factor α is used to modify Eq. (6) into Eq. (7) that resolves pressure dependence for all outgoing interface fluxes, and therefore resolving pressure dependence of the upstream mobility. Interface flux is a function of mobility, e.g., as shown in Eq (7). To resolve pressure/potential dependence of flux involves resolving pressure/potential dependence of upstream mobility. In one or more embodiments, the factor α is calculated by performing the λ_{TGMM} versus pressure integration of the right-hand side numerator in Eq. (8). The calculation is performed for each outgoing interface flux with known upstream and downstream pressures, and the integration is performed numerically by looking up and/or interpolating the pressure versus λ_{TGMM} value pairs in the drainage pseudo-pressure table. In one or more embodiments, the numerical integration approximates the integrated area defined by the sequence of pressure versus λ_{TGMM} value pairs as a sequence of trapezoidal shapes. Further details of performing Step 202 are described in reference to FIG. 2B below.

In Step 203, the calculated factor α is used to compute the interface fluxes for the grid blocks in the wellbore drainage region to account for the condensate banking effect during the reservoir simulation. As noted above, the pressure dependence of upstream mobility is resolved in modeling the condensate banking effect to generate the simulation result. In other words, the calculated factor α improves the accuracy of the reservoir simulation result to facilitate the well production operations.

In Step 204, well production operations of the reservoir are performed based on the reservoir simulation result. For example, Step 200 to Step 203 may be performed for each of a large number (e.g., 1000) wells of the reservoir to generate the reservoir simulation result. Such simulation result accounts for the condensate banking effect of these large number (e.g., 1000) of wells of the reservoir with enhanced accuracy to facilitate the well production operations of the entire reservoir.

FIG. 2B shows details of performing Step 201 and Step 202, i.e., constructing the drainage pseudo-pressure table and calculating the drainage pseudo-pressure factor α. Step 210 through Step 217 are performed for each grid block in the wellbore drainage region and at the beginning of each time step of the reservoir simulation.

Referring to FIG. 2B, initially in Step 210, the integration pressure/potential range of the drainage pseudo-pressure table of a particular grid block is established. The integration range corresponds to Øᵤₚₛₜᵣₘ and Ø_{dwnstrm} in the integral of Eq. (8) above. In one or more embodiments, the pressure at the center of the grid block defines the lower limit (i.e., minimum potential Øᵤₚₛₜᵣₘ) of the drainage pseudo-pressure table, while the maximum pressure of all neighboring grid blocks together with gravity head is used as the upper pressure limit Ø_{dwnstrm} of the drainage pseudo-pressure table. The integration pressure/potential range (i.e., difference between Øᵤₚₛₜᵣₘ and Ø_{dwnstrm}) are divided by a user defined pressure increment 60 to determine the number of entries in the drainage pseudo-pressure table.

In Step 211, the first four columns (i. e., ρ_{g}, ρₒ, μ_{g}, μₒ) of the drainage pseudo-pressure table plus liquid and vapor hydrocarbon moles L and V of the particular grid block are calculated for each entry in the drainage pseudo-pressure table. In one or more embodiments, Step 211 is performed by flash calculation using equation of state (EOS) for vapor/liquid-equilibrium (VLE).

In Step 212, a determination is made as to whether the pressure of a particular entry in the drainage pseudo-pressure table is below the dew point pressure or not. If the determination is positive, i.e., the pressure of the particular entry is below the dew point pressure and the liquid hydrocarbon moles in the grid block is above zero, the method proceeds to Steps 213 and 214 where the fifth through seventh columns

$$( R = \frac{L \times {μ}_{o} \times {ρ}_{g}}{V \times {μ}_{g} \times {ρ}_{o}} , {k}_{rg} , {k}_{ro} )$$

of the drainage pseudo-pressure table are calculated using Eq. (9) and the adaptive saturation lookup table, such as TABLE 1 and TABLE 3. For example, k_{rg} and kᵣₒ are computed by interpolating R given by Eq. (9), and using the adaptive saturation lookup table of sₒ versus kᵣₒ/k_{rg} relationship.

If the determination in Step 212 is negative, i.e., the pressure of the particular entry is above the dew point pressure and the liquid hydrocarbon moles in the grid block is zero, the method proceeds to Step 215 where the fifth through seventh columns

$$( R = \frac{L \times {μ}_{o} \times {ρ}_{g}}{V \times {μ}_{g} \times {ρ}_{o}} , {k}_{rg} , {k}_{ro} )$$

of the drainage pseudo-pressure table are calculated by assigning R and kᵣₒ to zero while leaving k_{rg} unchanged from the previous entry where the pressure is below the dew point pressure.

In Step 216 subsequent to Step 214 or Step 215, the total generalized molar mobility λ_{TGMM} is calculated using Eq. (5A). The calculated λ_{TGMM} is then used in Step 217 to calculate the drainage-pseudo-pressure factor α using Eq. (8). The calculated factor α is the eighth column of the drainage pseudo-pressure table.

At the beginning of each simulation time step and for a particular grid block in the wellbore drainage region, Step 200 and Step 201 are performed once while Step 212 through Step 217 are iteratively performed for each table entry to complete the drainage pseudo-pressure table for the particular grid block. This process is then iteratively performed for each grid block in the wellbore drainage region.

FIGS. 3A-3H show an implementation example in accordance with one or more embodiments. Gas condensate reservoirs have a significant share of the world's gas supply. Recovered condensate of these reservoirs has a high value in the market. However, when the reservoir pressure declines below the dew point pressure, liquid may drop out of gas condensate inside the reservoir and may leave a significant part of the condensate irrecoverable. In particular, the recovery factor for rich gas condensate reservoirs is very low due to severe condensate banking phenomena. The implementation example shown in FIGS. 3A-3H is based on the system and method flowchart described in reference to FIGS. 1A, 1B, 2A, and 2B above that generate accurate reservoir simulation result to improve the recovery of condensate and realize the economic value of gas condensate reservoirs.

Specifically, FIGS. 3A-3H illustrate a test case that validates using the drainage pseudo-pressure factor to achieve comparable simulation accuracy of using local grid refinement (LGR) in reservoir simulation. The reservoir grid without LGR is shown in FIGS. 3B and 3C where the reservoir grid (161) includes 21×21 grid blocks and 106 layers that are uniform with respect to area. Grid block size in each areal direction is 100 m and layer thickness is 5 m. In particular, FIG. 3C illustrates the test case with the example wellbore drainage region (305) centering at the perforated grid block A (161a) in the reservoir grid (161). FIG. 3D illustrates the heterogeneous condensate saturation map extending to the wellbore drainage region (305) according to the legend (306) where “SOIL” corresponds to “Saturation of oil”.

In the test case, rock properties are specified by oil-water and oil-gas saturation tables, with minimum residual saturations of water S_{orw}=0.17 (S_{wc}=0.05) and that of gas S_{org}=0.12 (S_{gc}=0.17) in their respective two-phase system. Stone-II model is used to interpolate three phase relative permeability from the two-phase data. Flow field is governed by a 5.0 inch diameter vertical well, which has perforations completed all the way from 41 to 89 layers. In each completed layer, skin=−2.65 is specified, this is to account for fracking and/or stimulation. The well produces at 12000 Mscf/day and minimum flowing bottom hole pressure (BHP) is limited to 700 psi. TABLE 4 shows further details of the test case.

TABLE 4

| Property distribution | Minimum | Maximum | Average |
|---|---|---|---|
| Permeability: kₓ = k_{y} | 0.001 mD | 64 mD | 1.72 mD |
| Porosity | 0.00 | 0.24 | 0.0632 |

In contrast to the reservoir grid (161) depicted in FIGS. 3C and 3D, FIG. 3C shows the reservoir grid (162) with LGR together with the condensate saturation map according to the legend (306).

FIG. 3F shows the reservoir simulation results comparing the coarse grid simulation result of the gas production rate (321) and FBHP (321a) to the LGR simulation result of the gas production rate (322) and FBHP (322a). The term “coarse grid” refers to the reservoir grid (161) with areal dimension of 100 m, as depicted in FIGS. 3C and 3D above. In FIG. 3F, the vertical axis corresponds to the gas rate and FBHP while the horizontal axis corresponds to the year of well production in the simulation.

Regardless of using the coarse grid or the LGR, upstream mobility is used in the reservoir simulation. However, for coarse grid with large size grid blocks, pressure dependence of rock and flow properties is significant due to high pressure drop across the grid block interfaces. On the other hand, for the LGR approach, pressure drop across the interfaces is relatively small and assumption of upstream mobility is valid and found to yield more accurate results.

In particular, the reservoir simulation using the coarse grid is based on Eq. (2) of the conventional well-model and does not include any pseudo-pressure and/or drainage-pseudo-pressure considerations. Accordingly, FIG. 3F shows that the condensate banking is not accounted in the coarse grid gas production rate (321) and coarse grid FBHP (321a) where the use of upstream mobility leads to over prediction (321b, 322b) of the performance of the well. In comparison, the LGR simulation result predicts a more realistic scenario that the well is unable to maintain a longer production rate plateau and is constrained by minimum specified BHP.

While the use of LGR in near well regions improves the accuracy of numerical results of the reservoir simulation, it comes with added computational cost and increase in simulation run time. FIG. 3G shows simulation run time comparison between the coarse grid and the LGR while utilizing the same computation resources for the test case. In FIG. 3G the vertical axis corresponds to simulation run time while the horizontal axis corresponds to the year of production during the reservoir simulation. In particular, the simulation run time curve (326) shows the simulation run time of 60 min for simulating the well production from year 2000 till year 2020 using the LGR approach. In comparison, the simulation run time curve (325) shows the simulation run time of 10 min for simulating the well production from year 2000 till year 2020 using the coarse grid. Similarly, the simulation run time curve (327) shows the simulation run time of 15 min for simulating the well production from year 2000 till year 2020 using the modified coarse grid with the drainage pseudo-pressure factor. For large scale reservoir simulation involving thousands of wells in the field, the use of LGR is associated with significant computational cost, and is impractical.

To balance the simulation result accuracy and the simulation run time, the drainage pseudo-pressure factor approach described in reference to TABLE 1 to TABLE 3 above can be used on a coarse grid to resolve pressure dependence of upstream fluxes extending to the wellbore drainage region without increasing grid resolution.

In TABLE 2, the drainage pseudo-pressure table, Ø_{Gi} and Ø_{Gj} denotes downstream and upstream potential, respectively of a grid block interface Γᵢⱼ. Note that λ_{TGMM} changes significantly across the phase transition from Ø_{Gi}+7δØ to Ø_{Gi}+8δØ. In conventional reservoir simulation, the upstream mobility is used (λ_{TGMM}=27.903), and is significantly different from that of the downstream mobility (λ_{TGMM}=5.0502). In order to bridge this difference, an effective/integrated upstream mobility is used to resolve the pressure dependence of rock and flow properties.

FIG. 3H shows the reservoir simulation results comparing the coarse grid simulation result of the gas production rate (321) without pseudo-pressure consideration, the LGR simulation result of the gas production rate (322), the modified coarse grid simulation result of the gas production rate (323) with pseudo-pressure consideration, and the modified coarse grid simulation result of the gas production rate (324) with the drainage pseudo-pressure factor. In FIG. 3H, the vertical axis corresponds to the gas rate while the horizontal axis corresponds to the year of well production in the simulation.

In generating the modified coarse grid simulation result of the gas production rate (323), conventional pseudo-pressure consideration (i.e., Eq. (4)) is limited to the perforated grid block and resolves pressure dependence of upstream mobility only partially. In generating the modified coarse grid simulation result of the gas production rate (324), the drainage pseudo-pressure factor is used to resolve pressure dependence of upstream mobility extending to the wellbore drainage region and yields results which are comparable to the LGR simulation result of the gas production rate (322). Note that the simulation with the drainage pseudo-pressure factor does not require fine grid resolution and is computationally more efficient than the simulation with the LGR approach.

Embodiments may be implemented on a computer system. FIG. 4 is a block diagram of a computer system (402) used to provide computational functionalities associated with described algorithms, methods, functions, processes, flows, and procedures as described in the instant disclosure, according to an implementation. The illustrated computer (402) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (402) may include a computer that includes an input device, such as a keypad, keyboard, touch screen, or other device that can accept user information, and an output device that conveys information associated with the operation of the computer (402), including digital data, visual, or audio information (or a combination of information), or a GUI.

The computer (402) can serve in a role as a client, network component, a server, a database or other persistency, or any other component (or a combination of roles) of a computer system for performing the subject matter described in the instant disclosure. The illustrated computer (402) is communicably coupled with a network (430). In some implementations, one or more components of the computer (402) may be configured to operate within environments, including cloud-computing-based, local, global, or other environment (or a combination of environments).

At a high level, the computer (402) is an electronic computing device operable to receive, transmit, process, store, or manage data and information associated with the described subject matter. According to some implementations, the computer (402) may also include or be communicably coupled with an application server, e-mail server, web server, caching server, streaming data server, business intelligence (BI) server, or other server (or a combination of servers).

The computer (402) can receive requests over network (430) from a client application (for example, executing on another computer (402)) and responding to the received requests by processing the said requests in an appropriate software application. In addition, requests may also be sent to the computer (402) from internal users (for example, from a command console or by other appropriate access method), external or third-parties, other automated applications, as well as any other appropriate entities, individuals, systems, or computers.

Each of the components of the computer (402) can communicate using a system bus (403). In some implementations, any or all of the components of the computer (402), both hardware or software (or a combination of hardware and software), may interface with each other or the interface (404) (or a combination of both) over the system bus (403) using an application programming interface (API) (412) or a service layer (413) (or a combination of the API (412) and service layer (413). The API (412) may include specifications for routines, data structures, and object classes. The API (412) may be either computer-language independent or dependent and refer to a complete interface, a single function, or even a set of APIs. The service layer (413) provides software services to the computer (402) or other components (whether or not illustrated) that are communicably coupled to the computer (402). The functionality of the computer (402) may be accessible for all service consumers using this service layer. Software services, such as those provided by the service layer (413), provide reusable, defined business functionalities through a defined interface. For example, the interface may be software written in JAVA, C++, or other suitable language providing data in extensible markup language (XML) format or other suitable format. While illustrated as an integrated component of the computer (402), alternative implementations may illustrate the API (412) or the service layer (413) as stand-alone components in relation to other components of the computer (402) or other components (whether or not illustrated) that are communicably coupled to the computer (402). Moreover, any or all parts of the API (412) or the service layer (413) may be implemented as child or sub-modules of another software module, enterprise application, or hardware module without departing from the scope of this disclosure.

The computer (402) includes an interface (404). Although illustrated as a single interface (404) in FIG. 4, two or more interfaces (404) may be used according to particular needs, desires, or particular implementations of the computer (402). The interface (404) is used by the computer (402) for communicating with other systems in a distributed environment that are connected to the network (430). Generally, the interface (404) includes logic encoded in software or hardware (or a combination of software and hardware) and operable to communicate with the network (430). More specifically, the interface (404) may include software supporting one or more communication protocols associated with communications such that the network (430) or interface's hardware is operable to communicate physical signals within and outside of the illustrated computer (402).

The computer (402) includes at least one computer processor (405). Although illustrated as a single computer processor (405) in FIG. 4, two or more processors may be used according to particular needs, desires, or particular implementations of the computer (402). Generally, the computer processor (405) executes instructions and manipulates data to perform the operations of the computer (402) and any algorithms, methods, functions, processes, flows, and procedures as described in the instant disclosure.

The computer (402) also includes a memory (406) that holds data for the computer (402) or other components (or a combination of both) that can be connected to the network (430). For example, memory (406) can be a database storing data consistent with this disclosure. Although illustrated as a single memory (406) in FIG. 4, two or more memories may be used according to particular needs, desires, or particular implementations of the computer (402) and the described functionality. While memory (406) is illustrated as an integral component of the computer (402), in alternative implementations, memory (406) can be external to the computer (402).

The application (407) is an algorithmic software engine providing functionality according to particular needs, desires, or particular implementations of the computer (402), particularly with respect to functionality described in this disclosure. For example, application (407) can serve as one or more components, modules, applications, etc. Further, although illustrated as a single application (407), the application (407) may be implemented as multiple applications (407) on the computer (402). In addition, although illustrated as integral to the computer (402), in alternative implementations, the application (407) can be external to the computer (402).

There may be any number of computers (402) associated with, or external to, a computer system containing computer (402), each computer (402) communicating over network (430). Further, the term “client,” “user,” and other appropriate terminology may be used interchangeably as appropriate without departing from the scope of this disclosure. Moreover, this disclosure contemplates that many users may use one computer (402), or that one user may use multiple computers (402).

In some embodiments, the computer (402) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AIaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method to perform reservoir simulation of a reservoir, comprising:
constructing a wellbore drainage region for a wellbore in a reservoir grid for the reservoir simulation;
constructing a drainage pseudo-pressure table for each grid block in the wellbore drainage region;
calculating, based on the drainage pseudo-pressure table, a drainage pseudo-pressure factor for said each grid block in the wellbore drainage region;
performing, based on the drainage pseudo-pressure factor for said each grid block in the wellbore drainage region, the reservoir simulation of the reservoir to generate a reservoir simulation result; and
performing, based on the reservoir simulation result, well production of the reservoir,
wherein the drainage pseudo-pressure factor is used in the reservoir simulation to model a condensate banking phenomenon in the wellbore drainage region.

2. The method of claim 1, wherein modeling the condensate banking phenomenon in the wellbore drainage region comprises:
computing, based on the drainage pseudo-pressure factor, grid block interface fluxes in the wellbore drainage region to resolve pressure dependence of upstream mobility.

3. The method of claim 1,
wherein the wellbore drainage region is constructed by traversing the reservoir grid from a perforated grid block within a user specified cut off distance, and
wherein the perforated grid block in the reservoir grid corresponds to a wellbore in the reservoir.

4. The method of claim 1,
wherein the wellbore drainage region is constructed by traversing the reservoir grid from a perforated grid block based on a user specified cut off flux fraction,
wherein the perforated grid block in the reservoir grid corresponds to a wellbore in the reservoir,
wherein the flux fraction corresponds to a ratio of a grid block interface flux over a wellbore inflow flux,
wherein a first grid block associated with a first flux fraction exceeding the user specified cut off flux fraction is included in the wellbore drainage region, and
wherein a second grid block associated with a second flux fraction less than the user specified cut off flux fraction is excluded from the wellbore drainage region.

5. The method of claim 1,
wherein the wellbore drainage region is constructed by traversing the reservoir grid from a perforated grid block based on a user specified minimum drainage level,
wherein the perforated grid block in the reservoir grid corresponds to a wellbore in the reservoir, and
wherein the drainage level of a grid block corresponds to a hop-distance of the grid block from the perforated grid block.

6. The method of claim 1, wherein constructing the drainage pseudo-pressure table comprises:
computing a pressure versus total generalized molar mobility (λ_{TGMM}) value pair for each entry of the drainage pseudo-pressure table.

7. The method of claim 6, wherein calculating the drainage pseudo-pressure factor comprises:
computing, for said each grid block in the wellbore drainage region, a pseudo-pressure integral based on the pressure versus λ_{TGMM} value pair for each entry of the drainage pseudo-pressure table.

8. A reservoir simulator to perform reservoir simulation of a reservoir, comprising:
a computer processor; and
memory storing instructions, when executed by the computer processor comprising functionality for:
constructing a wellbore drainage region for a wellbore in a reservoir grid for the reservoir simulation;
constructing a drainage pseudo-pressure table for each grid block in the wellbore drainage region;
calculating, based on the drainage pseudo-pressure table, a drainage pseudo-pressure factor for said each grid block in the wellbore drainage region;
performing, based on the drainage pseudo-pressure factor for said each grid block in the wellbore drainage region, the reservoir simulation of the reservoir to generate a reservoir simulation result; and
facilitating, based on the reservoir simulation result, well production of the reservoir,
wherein the drainage pseudo-pressure factor is used in the reservoir simulation to model a condensate banking phenomenon in the wellbore drainage region.

9. The reservoir simulator of claim 8, wherein modeling the condensate banking phenomenon in the wellbore drainage region comprises:
computing, based on the drainage pseudo-pressure factor, grid block interface fluxes in the wellbore drainage region to resolve pressure dependence of upstream mobility.

10. The reservoir simulator of claim 8,
wherein the wellbore drainage region is constructed by traversing the reservoir grid from a perforated grid block within a user specified cut off distance, and
wherein the perforated grid block in the reservoir grid corresponds to a wellbore in the reservoir.

11. The reservoir simulator of claim 8,
wherein the wellbore drainage region is constructed by traversing the reservoir grid from a perforated grid block based on a user specified cut off flux fraction,
wherein the perforated grid block in the reservoir grid corresponds to a wellbore in the reservoir,
wherein the flux fraction corresponds to a ratio of a grid block interface flux over a wellbore inflow flux,
wherein a first grid block associated with a first flux fraction exceeding the user specified cut off flux fraction is included in the wellbore drainage region, and
wherein a second grid block associated with a second flux fraction less than the user specified cut off flux fraction is excluded from the wellbore drainage region.

12. The reservoir simulator of claim 8,
wherein the wellbore drainage region is constructed by traversing the reservoir grid from a perforated grid block based on a user specified minimum drainage level,
wherein the perforated grid block in the reservoir grid corresponds to a wellbore in the reservoir, and
wherein the drainage level of a grid block corresponds to a hop-distance of the grid block from the perforated grid block.

13. The reservoir simulator of claim 8, wherein constructing the drainage pseudo-pressure table comprises:
computing a pressure versus total generalized molar mobility (λ_{TGMM}) value pair for each entry of the drainage pseudo-pressure table.

14. The reservoir simulator of claim 13, wherein calculating the drainage pseudo-pressure factor comprises:
computing, for said each grid block in the wellbore drainage region, a pseudo-pressure integral based on the pressure versus λ_{TGMM} value pair for each entry of the drainage pseudo-pressure table.

15. A system comprising:
a wellbore for performing well production of a reservoir; and
a reservoir simulator comprising a computer processor and memory storing instructions, when executed by the computer processor comprising functionality for:
constructing a wellbore drainage region for the wellbore in a reservoir grid for the reservoir simulation;
constructing a drainage pseudo-pressure table for each grid block in the wellbore drainage region;
calculating, based on the drainage pseudo-pressure table, a drainage pseudo-pressure factor for said each grid block in the wellbore drainage region;
performing, based on the drainage pseudo-pressure factor for said each grid block in the wellbore drainage region, the reservoir simulation of the reservoir to generate a reservoir simulation result; and
facilitating, based on the reservoir simulation result, well production of the reservoir,
wherein the drainage pseudo-pressure factor is used in the reservoir simulation to model a condensate banking phenomenon in the wellbore drainage region.

16. The system of claim 15, wherein modeling the condensate banking phenomenon in the wellbore drainage region comprises:
computing, based on the drainage pseudo-pressure factor, grid block interface fluxes in the wellbore drainage region to resolve pressure dependence of upstream mobility.

17. The system of claim 15,
wherein the wellbore drainage region is constructed by traversing the reservoir grid from a perforated grid block within a user specified cut off distance, and
wherein the perforated grid block in the reservoir grid corresponds to a wellbore in the reservoir.

18. The system of claim 15,
wherein the wellbore drainage region is constructed by traversing the reservoir grid from a perforated grid block based on a user specified cut off flux fraction,
wherein the perforated grid block in the reservoir grid corresponds to a wellbore in the reservoir,
wherein the flux fraction corresponds to a ratio of a grid block interface flux over a wellbore inflow flux,
wherein a first grid block associated with a first flux fraction exceeding the user specified cut off flux fraction is included in the wellbore drainage region, and
wherein a second grid block associated with a second flux fraction less than the user specified cut off flux fraction is excluded from the wellbore drainage region.

19. The system of claim 15,
wherein the wellbore drainage region is constructed by traversing the reservoir grid from a perforated grid block based on a user specified minimum drainage level,
wherein the perforated grid block in the reservoir grid corresponds to a wellbore in the reservoir, and
wherein the drainage level of a grid block corresponds to a hop-distance of the grid block from the perforated grid block.

20. The system of claim 15,
wherein constructing the drainage pseudo-pressure table comprises computing a pressure versus total generalized molar mobility (λ_{TGMM}) value pair for each entry of the drainage pseudo-pressure table, and
wherein calculating the drainage pseudo-pressure factor comprises computing, for said each grid block in the wellbore drainage region, a pseudo-pressure integral based on the pressure versus λ_{TGMM} value pair for each entry of the drainage pseudo-pressure table.
